(19) United States
(12) Patent Application Publication
(10) Pub. No.: US 2026/0369519 A1
(43) Pub. Date: Nov. 19, 2026

(54) FRAME-BASED PRECESSION MAPPING IN ELECTRON MICROSCOPY

(71) Applicant: FEI Company, Hillsboro, OR (US)

(72) Inventors: Bert Henning Freitag, Weilerswist (DE); Peter Christiaan Tiemeijer, Eindhoven (NL); Erik Rene Kieft, Eindhoven (NL)

(21) Appl. No.: 19/132,311

(22) PCT Filed: Nov. 16, 2023
(86) PCT No.: PCT/US2023/080015

§ 371 Date: May 22, 2025

Related U.S. Application Data
(60) Provisional application No. 63/427,643, filed on Nov. 23, 2022.

(51) Int. Cl. H01J 37/28; H01J 37/147

(52) U.S. Cl. CPC H01J 37/28; H01J 37/1474; H01J 2237/221

(57) ABSTRACT

Methods include directing a charged particle beam across an area of a target at a first angle having tilt and azimuth angle components, to collect a first image frame produced using the beam at the selected first angle, detecting the first image frame, directing the charged particle beam across the area of the target at a second angle having tilt and/or azimuth angle components different from the first angle tilt and azimuth angle components to collect a second image frame produced using the beam at the selected second angle, detecting the second image frame, and combining the first and second image frames to form an image. Related apparatus are also disclosed.

### CROSS REFERENCE TO RELATED APPLICATION

This application claims priority to U.S. Provisional Application No. 63/427,643, filed Nov. 23, 2022, the entire application being incorporated by referenced herein.

### FIELD

The field is charged particle beam microscopy.

### BACKGROUND

In many areas of electron microscopy, such as electron energy loss spectroscopy (EELS) and energy dispersive x-ray spectroscopy (EDX), samples are probed to determine chemical composition of, e.g., crystalline materials. However, at least in EELS and EDX, it can be difficult to determine chemical composition because the spectroscopic signal can vary with sample orientation due to channeling of the beam through the crystal. Characteristic peak signal strength of spectroscopic data of a sample can be made less dependent on sample orientation by impinging an electron beam on the sample in a specific pattern in which the beam is scanned over time at a particular sample location at a tilt angle, i.e., through a conical scan path. In particular, the tilt angle can be optimized so that a characteristic spectroscopic peak is saturated and dynamical scattering is suppressed. However, the existing approaches include numerous drawbacks that limit the potential benefits of scanning at a tilt angle, and thus a need remains for improved systems and methods.

### BRIEF DESCRIPTION OF THE DRAWINGS

FIG. 1 is a flowchart of various examples of frame-based imaging methods.

FIGS. 2A-2B are perspective and plan views, respectively, of a sample receiving a beam in the collection of a frame, according to some examples.

FIG. 3 is a side view schematic of an example frame-based charged particle beam imaging system, according to various examples.

FIG. 4 is a plan view schematic of an example scan area of a sample and associated tilt/azimuth data that is collected with a series of frames.

FIG. 5 is a flowchart of drift and/or aberration correction methods according to some examples.

FIG. 6 is a flowchart of example 3D imaging methods.

### DETAILED DESCRIPTION

### Introduction to Tilt Precession Approaches and Overview of Frame-Based Techniques

In transmission electron microscope spectroscopy and imaging applications, precession of a beam while the beam is scanned can be used to improve performance. This is normally done by precessing the beam on a cone in each point of the scan, e.g., by dwelling at a position and acquiring pixel data over time as the beam precesses through the cone (hereinafter “pixel-based” approaches). In various applications, precession is performed instead of on-axis imaging in order to improve imaging characteristics, for example, to avoid channeling artifacts in spectroscopy, to separate integrated center-of-mass (iCOM) effects of phase shifts in crystals from field contributions, or to increase intensities in higher order diffraction spots for more accurate strain analysis.

Herein, examples are disclosed which involve precession imaging but do not necessarily involve precessing a probe beam on a cone in each point of a scan. Rather, disclosed precession workflow examples can include frame-based collection. With frame-based collection, a particular precession (or tilt) angle and azimuth can be selected and an array of pixels are recorded at the selected precession angle and azimuth. The recorded array of pixels can correspond to a frame of a frame-based precession workflow. One or more additional frames can then be collected using one or more respective different selected precession angles and/or azimuths being changed to a new angle and/or azimuth. In some examples, the quantity and associated precession angle characteristics of the collected frames can include a set of data commensurate with the amount of data collected by precessing a beam on a cone in each individual pixel of a frame, such as with pixel-based techniques. Stated differently, rather than recording dynamically tilted beams in a single pixel during a full scan of the frame, a frame can be scanned quickly with a fixed beam tilt and then the frame scanning can be repeated with additional tilts until a tilt matrix similar to that obtained through the pixel-based approach is sufficiently filled.

However, various frame-based examples herein can exhibit enhanced characteristics over pixel-based approaches and/or allow for various improvements. For example, frame-based approaches can allow for the implementation of various correction capabilities during the workflow that would be impractical or impossible in pixel-based approaches. Further, frame-based approaches can allow for significantly improved imaging speed over pixel-based approaches and can enable new applications that would be impractical or impossible with pixel-based approaches. That is, various frame-based examples can provide faster data acquisition times, improved spectroscopic image quality, improved field and strain measurements, and new applications such as atomic 3D imaging, rocking mapping, dancing beam aberration correction in STEM, etc.

Thus, while multiple applications exist that might benefit from precession mapping techniques, or a tilted beam incidence more generally, such applications have so far been limited by the existing precession paradigm in which a fixed tilt amplitude is applied to a focused beam that is then scanned about a conical path at a specific point on a sample. In contrast, systems and approaches described herein which use frame-based precession allow for considerable flexibility in the construction of a tilt matrix of data. This flexibility can allow precession techniques to expand to new applications such as 3D imaging and can open precession collection to further imaging refinements such as drift correction.

Electron microscopes can be equipped with sets of deflectors for generating shifts and/or tilts of the beam at the sample. These can be accomplished by placing a first deflector in a plane that is exactly conjugate to the sample thus guaranteeing that this first deflector creates only a tilt at the sample (and no shift), and by placing a second deflector in a plane that is exactly conjugate to the front focal plane of the probe forming lens thus guaranteeing that this second deflector creates only a shift at the sample (and no tilt). However, it is more common and more flexible to place two deflectors in two distinct planes (e.g., an upper plane and a lower plane), which are not necessarily conjugate to the sample or the front focal plane of the objective lens, and to excite the upper deflector and the lower deflector at two specific ratios which first ratio is tuned such that the two deflectors together create a pure shift at the sample, and which second ratio is tuned such that the two deflectors together create a pure tilt at the sample. The tuning of these ratios is commonly referred to as ‘tuning the pivot points’.

The focal strength of the probe forming lens somewhat varies with the applied tilt angle at the specimen due to the aberrations of this lens, especially its spherical aberration. Because of this variation, the exact position of the plane conjugate to the sample also varies somewhat with the applied tilt angle. For the same reason, the exact value of the pivot points also vary somewhat with the applied tilt. Correction of these variations can require sophisticated compensation schemes for the pivot points when dynamically varying tilts are applied. The applied tilt angle when combined with the aberrations of the probe forming lens, does not only induce variation of focus but can also induce variations of astigmatism and/or coma which compromise image resolution if not corrected (e.g., using stigmators and additional deflection).

Each deflector can include two perpendicular pairs of magnetic coils or two pairs of electrostatic deflection plates, to enable deflection in the two directions (x and y) perpendicular to the beam.

Deflectors based on magnetic coils are often easier to construct than deflectors based on electrostatic deflection plates, but magnetic coils typically have maximum scan rates below those of electrostatic deflection plates due to their self-inductance. Thus, some example microscope systems can include a combination of magnetic deflectors and electrostatic deflectors, such that the magnetic deflectors can be used for adjustments which can be permitted to operate with modest rates (such as beam tilt according to the present disclosure) and the electrostatic deflectors can be used for adjustments which can benefit from the highest rates such as fast lateral scanning.

Some microscope examples can include duplicate sets of deflectors upstream of the sample to similar sets of deflectors downstream of the sample, such that sets of deflectors downstream undo the shift and/or tilt applied at the sample to guarantee a stationary beam at the detectors downstream.

In many examples, frame-based precession techniques can realize improved performance by scanning fast with a static tilt and doing so multiple times according to a user defined tilt matrix rather than, e.g., tilting in each point to complete the tilt matrix as with pixel-based approaches. In many frame-based examples, separate beam deflectors can be used, e.g., with one providing fast lateral scanning of the probe across the sample and another providing the fixed (or slowly varying) tilt angle for a particular frame. In this way, tilt shift pivot point analyses and sophisticated compensation normally required when using only two dynamic deflector units (i.e., one to provide tilt and shift before the sample and one to de-scan the beam after the sample), are no longer needed in most applications. Moreover, degradation of the probe beam can then be limited to contributions by the optical system alone, such as aberrations introduced by the objective lens. Such aberrations can be more readily predicted with a model and therefore be partly corrected to achieve smaller probe sizes when tilting, resulting in improved optical performance for an array of applications.

Frame-based examples also can resolve longstanding problems associated with drift of the probe at the sample. For example, in pixel-based approaches each pixel is separately scanned through a cone until a full frame is completed. During this lengthy process, the probe and sample can drift relative to each other due to various influences on the system. This can reduce the quality of produced images in an already time-consuming acquisition process of collecting precession image components. In frame-based approaches, the drift can be compensated more easily as the speed of the acquisition of a single frame is considerably faster (high repetition rate) than the time required to complete a full frame using a pixel-based approach. Thus, drift is less likely to occur or have significant impact across an acquired frame that is scanned quickly at a fixed tilt. Where drift does have an impact, such as between frames or after several frames (e.g., after a change in azimuth or tilt angle), drift correction can be performed. By contrast, pixel-based methods do not allow for a frame-based drift correction.

Pixel-based methods typically only allow for a cone illumination with a fixed amplitude (e.g., a fixed tilt angle with respect to an optical axis) because the pivot points (shift & tilt) depend on this amplitude. With frame-based examples as taught herein, the additional flexibility in tilt angle and amplitude allows for the application of arbitrary tilt matrices, including, by way of example, rocking beam, random walk, precession, etc. In precession, a fixed tilt amplitude is typically applied to the beam and an azimuth direction is changed at the tilt amplitude, e.g., following a full 360-degree rotation of a circle. In rocking beam, a tilt amplitude is varied and typically run a cartesian squared pattern of the beam tilt with typically equal x, y steps (e.g., 3×3, 8×8, etc.). In random walk precession, a cartesian coordinate system of the beam tilt is used and the matrix is randomly visited with different tilts. This matrix does not need to be filled completely and so a sparse scan of the tilt matrix can be performed. For a rocking beam tilt matrix, the positions of the matrix can include a harmonic, Lissajous, or other path across the matrix. The harmonic, Lissajous path has the advantage that it can be scanned with scan coils without flyback issues caused by a line-by-line scan of the tilt amplitude.

With additional compensation options being made available in frame-based approaches, the degradation of the probe caused by the aberration of the objective lens (e.g., affecting each fixed tilt of the series of frames recorded) can be compensated, further allowing 3D atomic focus series acquisition. For example, a 100 mrad convergence half angle can be required to obtain an atomic resolution focal depth. With current technology, this can only be achieved by correcting all aberrations up to 100 mrad. Such corrections are difficult or impractical to achieve. However, by tilting a ~30 mrad beam in a tilt matrix (e.g., 3×3, 5×5, etc.) up to 100 mrad maximum tilt can be achieved. Probe aberrations in each frame can be partially corrected to maintain a ~0.2 nm probe size in the x, y plane. Thus, a minimum voxel in x, y, z position can be created allowing scanning in 3 dimensions by changing the focus in approximately angstrom sized steps.

### Example Frame-Based Methods

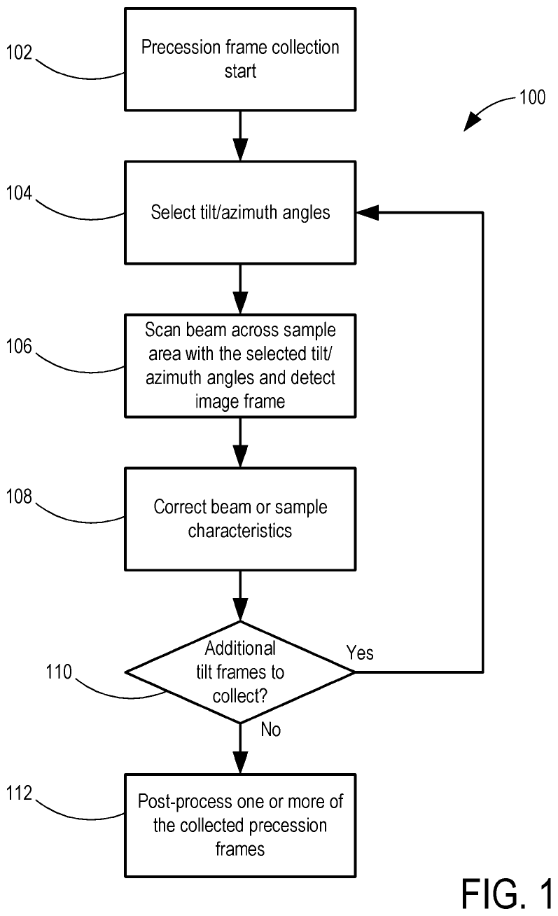

FIG. 1 is an example frame-based collection method 100. The method 100 includes an initiation of the frame collection method at 102. For example, a sample can be arranged in a chamber of a charged particle beam microscope, such as an electron microscope. A charged particle probe beam, such as an electron beam, is directed along an optical column of the microscope. The optical column can include an arrangement of lenses defining an optical axis. The optical axis of the system generally corresponds to a central axis of the optical column but in some examples it can be adjusted so that it is at an angle to the central axis. The lenses can be used to direct the probe beam along the optical axis and focus the beam towards the sample. The sample can be arranged to be in the path of the beam, e.g., on a fixed or movable stage. Before impinging on the sample, one or more probe beam deflectors (two separate beam deflectors in representative examples) can be used to direct the probe beam away from the optical axis, e.g., at an angle with respect to the optical axis and/or laterally with respect to the optical axis. One or more detectors can be arranged in relation to the sample to receive particle emission from the sample in the form of a detection beam. An additional detection beam deflector can be arranged to direct the detection beam from the sample to the detector, e.g., to de-tilt emitted particles. In representative examples, the detection beam is a beam that is downstream from the sample, and the additional beam deflector (or deflectors) can correspond to a downstream deflector. Various frame collection steps such as scanning, detecting, and/or changing beam parameters are typically automated by, for example, a system controller.

To collect a frame, at 104, a tilt angle (i.e., polar or inclination angle) and azimuth angle (which can be referred to collectively as a tilt angle or tilt angles) are selected for the probe beam that is to impinge on the sample. At 106, the probe beam is then scanned across the sample laterally in relation to the optical axis at the selected tilt and azimuth angles using the probe beam deflectors. The selected tilt angle and azimuth are fixed or maintained as the probe beam is scanned across the sample. In many examples, after interaction with the sample, a downstream beam is deflected with the detection beam deflector and detected at the detector. Various detectors may be used depending on the application. The collected frame can correspond to the data collected with the detector associated with the beam impinging at the multiple positions of the sample using the fixed or maintained tilt and azimuth. The multiple positions can be referred to as pixels.

In some examples, at 108, after a frame is collected, beam characteristics or sample characteristics can be corrected, e.g., to compensate for drift, sample perturbation, etc. At 110, a determination can be made whether to collect additional frames, e.g., to continue to collect additional frames according to an automated process or workflow (such as to complete a tilt matrix) or to rescan frames based on a determination made at 108. If additional frames are to be collected the process can revert to an earlier part of the process 100 and repeat, e.g., selecting or adjusting tilt/azimuth angles at 104 and scanning and detecting at 106. For one or more subsequent frames, the tilt angle and/or azimuth angle can be changed to one or more different angles that can also be maintained as the beam is scanned across the area of the sample in the generation of the one or more subsequent frames.

In additional examples, corrections at 108 can correspond to corrections associated with aberrations of the beam being directed to the sample, and such corrections can be more contemporaneous with frame collection. Aberrations can include defocus, astigmatism, coma, etc. For example, aberration corrections at 108 can occur before a frame is collected or between frames. Such corrections typically occur based on a model prediction of aberrations expected for selected deflection angles and/or scan positions. Aberrations can be corrected through adjustment to existing beam deflectors and/or lens elements as well as with additional components, such as stigmators, probe correctors, or aberration correction lenses (aberration correctors can include but are not limited to Cc and/or Cs correctors). Often, scan speed can exceed the response time capability of aberration correction devices. Thus, the command knowledge of the frames that are to be collected can allow for sufficient to time to make adjustments for aberrations, e.g., during the period between the collection of two frames or over the process of frame collection. In this way, compensation can occur with specific adjustments/improvements at each angle before scanning. Thus, such aberration corrections can occur without necessarily detecting those aberrations in quasi real time, as that detection part would often not be necessary. In many examples, a tilt/azimuth angle can be selected at 104, aberrations can be corrected for that particular angle at 108, and the beam can then be scanned across the sample and the image frame detected at 106.

In many examples, the fixed or maintained tilt and azimuth angles can be defined by a fixed (or sometimes slowly varying) azimuth angle in a reference plane perpendicular to the optical axis of the system and a fixed or slowly varying angle relative to a reference axis perpendicular to the reference plane. This stands in contrast to pixel-based precession approaches where the angle of incidence relative to the optical axis remains fixed (e.g., a 5° tilt angle) while the azimuth changes over time for a particular pixel so that detections can occur at one or more azimuth positions for that pixel (e.g., detections at 10° azimuth increments) before the beam is shifted to an adjacent pixel for similar precession to occur. In a basic frame-based precession example, a tilt matrix can be compiled by collecting a set of frames at a selected tilt angle with each frame varying its fixed azimuth angle by a selected amount. For example, a complete precession period can be collected with 36 frames, each frame collected at a 5° tilt angle and having its azimuth angle stepped in 10° increments. It will be appreciated that a host of tilt and azimuth sequences may be used in various frame-based collection examples, such as precession, harmonic, Lissajous, rocking, etc., sequences. In many examples, frame sequences include many tilt and/or azimuth angles, e.g., two or more frames, three or more frames, four or more frames, ten or more frames, fifty or more frames, etc.

In many frame-based examples, the angle of the probe beam can be maintained at an intersection with the sample. In some instances where a sample surface is flat and angled obliquely (i.e., not perpendicular) relative to the optical axis of the system, the fixed tilt angle and azimuth angle can be maintained across the angled sample surface throughout the collection of a frame. For example, z-focus adjustments can be made to the beam as the z-position of the sample varies across the frame. In more typical examples, the sample is arranged generally perpendicular to a central optical axis of the system. In some examples, frames can be collected at different focus depths, e.g., in 3D depth sectioning. At 112, various post-processing of the collected frames can be performed, such as mapping pixels between frames, drift correction, shift compensation, 3D depth sectioning, frame summing, etc. In many examples, particularly in EDX, EELS, or spectroscopic modalities more generally, images can be summed to form an average, or combined, image, e.g., a combined diffraction image.

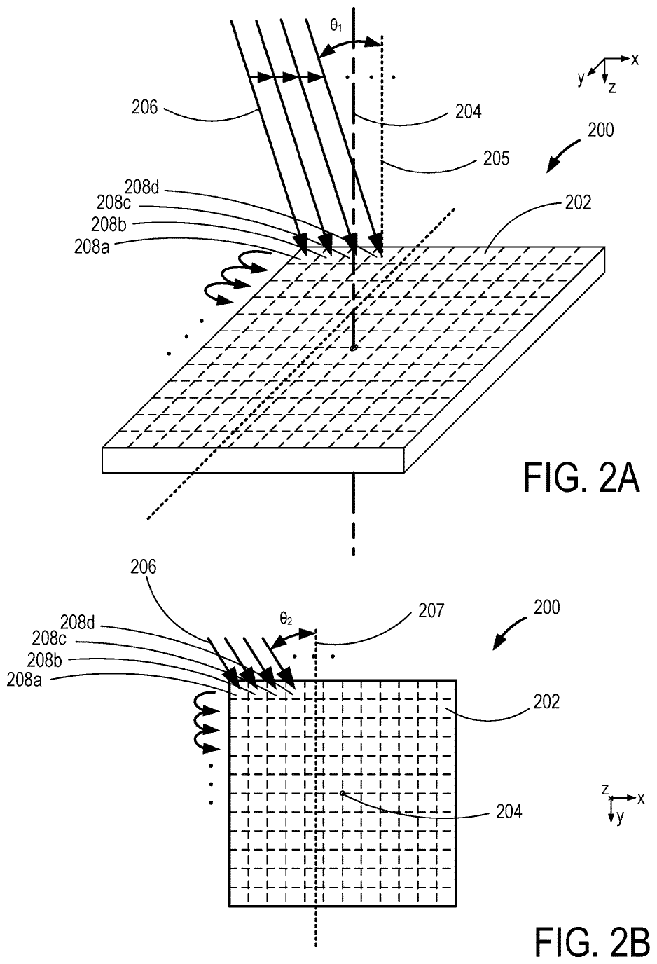

FIGS. 2A-2B is an example of a sample 200 being probed with a frame-based probing method, such as method 100. The sample 200 is arranged in a chamber of an electron microscope. A surface 202 is perpendicular to and generally centered in relation to an optical axis 204 of the electron microscope. To collect a frame, a probe beam 206 is directed to the surface 202 at a selected tilt angle θ₁ (shown with respect to a reference line 205 parallel to the optical axis 204) and azimuth angle θ₂ (shown with respect to a reference line 207 that is perpendicular to the optical axis 204) that generally remain fixed as the probe beam 206 is scanned across the frame. As shown, the probe beam 206 is scanned laterally across the frame through four sequential positions 208a-208d and through multiple rows. The lateral scanning can occur relatively quickly, e.g., within microseconds, which can ensure that many types of drift-related aberrations do not affect the data collected across the frame. As shown a rectilinear grid is shown though it will be appreciated that an arbitrary grid may be selected. While scanning across a frame can occur in a sequential manner across adjacent pixels, other patterns may be used.

### Microscopy Apparatus Examples

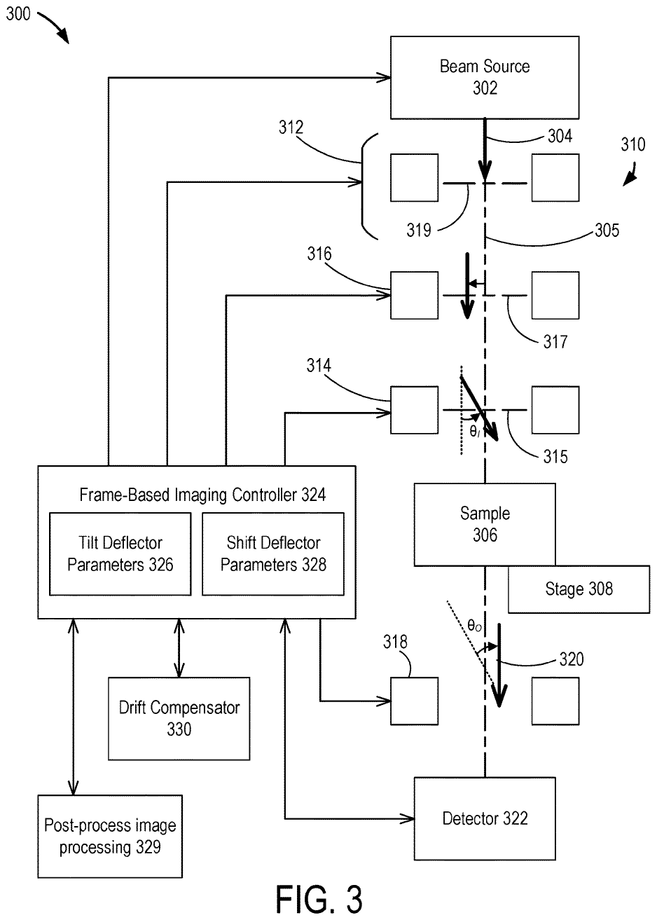

FIG. 3 is an example frame-based precession microscope system 300. The system 300 includes a charged particle beam (CPB) source 302, such as an electron or ion emitter source. The CPB source 302 emits a beam 304 that can be directed along an optical axis 305 to a sample 306 arranged on a stage 308. The system 300 can include a beam direction column 310 that typically includes an arrangement 312 of electrostatic lenses, magnetic lenses, and/or other components that are configured to shape and direct the beam 304 to the sample 306. Example lens and other components of the arrangement 312 can include condenser lens elements, objective lens elements, apertures, relay lenses, stigmators, deflectors, scan coils, beam modulators, aberration correctors, etc. The arrangement 312 is shown at a selected location nearer the beam source 302 but this is for convenience of illustration, as it will be appreciated that various lenses and components may be distributed throughout the optical column 310. For example, additional lens elements can be situated below the sample (such as with STEM examples) to focus transmitted or emitted particles on a detector 322.

The system 300 can include a tilt beam deflector 314 configured to adjust an angle of the beam 304 such that the beam 304 propagates to and is received by the sample 306 at an angle θₜ relative to the optical axis 305. The adjusted angle can be referred to as a tilt angle. The tilt beam deflector 314 can include magnetic coils and/or electrostatic plates that provides the tilt deflection, and the speed of changing the tilt can be relatively slow, e.g., once every frame, with 10 frames per second for a 512×512 pixel frame (~0.4 μs per pixel). In some examples, the tilt beam deflector 314 is located at a conjugate plane 315 to a portion of the sample 306 (e.g., a surface of the sample 306 or a z-layer located at a specified depth within the sample 306). The system 300 can include a shift beam deflector 316 configured to adjust a lateral position of the beam 304 such that the beam 304 propagates to and is received by the sample 306 at a shifted lateral position relative to the optical axis 305. In many examples, the shift beam deflector 316 can include an electrostatic deflector (often a pair of electrodes) configured to provide a relatively fast lateral scanning speed, which can be significantly faster than the tilt beam deflector, e.g., an order of magnitude greater, enabling rates such as 120 frames per second for a 512×512 pixel frame (~30 ns per pixel). In some examples, the shift beam deflector 316 is located at a conjugate plane 317 to a front focal plane 319 of a probe-forming lens in, for example, the arrangement 312.

In many examples, the sample 306 can be flat and arranged on the stage 308 so that the surface or targeted sample layer is perpendicular to the optical axis 305. In further examples, the surface or targeted layer of the sample 306 can be flat and arranged at an angle relative to the optical axis 305 and/or have a contour.

In various examples, the system 300 can focus the beam 304 onto the sample to cause various types of radiation to emanate from the sample 306, including (for example) transmitted electrons, secondary electrons, backscattered electrons, X-rays, and/or optical radiation (e.g., cathodoluminescence). The emanating radiation to be detected caused by interaction with the sample 306 can be referred to as a detection beam 320. In some examples, an additional beam deflector 318 can be situated to deflect the detection beam 320 so that the detection beam can be received by the detector 322. For example, the beam deflector 318 can operate in a complementary way to the tilt beam deflector 314, so as to de-tilt the beam 304 at an angle θ_{O}. The angles θₗ, θ_{O} are shown for convenience of illustration and need not be identical in magnitude. Further, the beam deflector 318 need not cause an angled detection beam 320 to propagate parallel to the optical axis 305.

The detector 322 can be of various types depending upon the application, and some example apparatus can include multiple types of detectors. As shown the detector is arranged below the sample 306, but other locations may be suitable depending on the type of detection being made. Suitable examples of the detector 322 can include segmented STEM detectors and/or pixelated detectors, which are typically arranged below the sample 306. Pixelated detectors can be arranged to acquire full diffraction patterns generated from the sample. In some pixelated examples, full STEM images can be obtained, including HAADF or dark field images. Pixelated STEM detectors can be used for common analysis, crystal orientation mapping, and strain mapping. Segmented STEM detectors can be used for acquisition of center of mass analysis data. In some examples, the detector 322 can include or correspond to an electron energy loss spectroscopy (EELS) sensor. EELS sensors are often used in chemical analysis applications. For many EELS crystallographic detections, channeling effects can adversely affect the collected data and such channeling effects can be overcome to a significant extent through precession of the beam 304. In some examples, the detector 322 can correspond to or include an x-ray energy dispersive spectroscopy (EDX) detector, an auger electron spectroscopy (AES) detector, secondary electron (SE) detector, and/or backscattered electron (BSE) detector, typically arranged in a position that is not below the sample 306. Example detectors can include CMOS sensors, CCD imaging sensors, photodetectors, etc.

The additional beam deflector 318 can be included in examples to compensate for a shift in a diffraction image present in the detection beam 320. Correcting such a shift is useful or required in EELS due to the change in collection angle caused by the shift in the diffraction pattern. In EDX mapping, it is typically not required because the signal is created above the specimen. In examples in which 4D STEM data is recorded on a pixelated detector below the specimen of each tilt, diffraction shifts caused by beam tilt can be corrected in software, e.g., separately during or after processing. In some examples, software routines can provide shift correction by summing collected diffraction patterns with different beam tilts in each scan point. For example, the central disk can be aligned in each pixel for all tilts and the diffraction patterns can be added.

The different components of the system 300 can be coupled and controlled by a frame-based imaging controller 324, which can correspond to or be part of a controller or control network of the system 300. The controller 324 can be coupled to the various components, such as the beam source 302, lens (etc.) arrangement 312, tilt, shift, and de-tilt beam deflectors 314, 316, 318, and detector 322, to control the direction of the beam to the sample 306 and detector 322 and detection of the beam 320. In many examples, the controller 324 can be preprogrammed with a frame-based detection routine that can include tilt deflector parameters 326 and shift deflector parameters 328 configured to adjust characteristics of the source beam 304 and detection beam 320. The shift beam deflector 316, which typically operates on much faster timescales than the tilt beam deflector 314, can provide the scanning of the beam 304 laterally with respect to the sample 306 across the frame. In some examples, the shift beam deflector parameters 328 can include a pixel mapping overlaid on a portion of the sample 306.

Pixel-based precession techniques typically rely on a single scan unit to precess a beam in each pixel. The pivot point alignment between tilt and shift in such techniques is a long-standing problem. That is, with a single scan unit, tilt and shift are intertwined and need to be decoupled to provide pivot point alignment of the precessing beam at the same position on the sample. For example, to provide the same tilt angle and a different azimuth angle, the beam requires shifting to maintain the probe beam at the same sample location. This results in complicated tilt matrices for scanning across the sample to compensate and ensure stability of the beam while the beam is being precessed. Moreover, tilt matrices require significant changes after changing tilt angle. In many examples the system 300, with the tilt beam deflection and shift beam deflection being provided by different deflectors 314, 316, the tilt beam deflection and shift beam deflection can be advantageously de-coupled from each other, greatly simplifying the workflow procedure of precession-based techniques as well as other techniques that include beam tilt. In some examples, the tilt beam deflector parameters 326 can include one or more tilt angles and one or more azimuth angles that can be applied to the beam 304.

Frame-based approaches can leverage the de-coupled tilt and shift beam deflection to achieve substantial improvements in workflow throughput and/or improved image quality. For example, in frame-based approaches, rather than repeat a slower change in azimuth or tilt angle for each pixel, the azimuth or tilt angle can be done fewer times (or just once) in a single frame across the sample area, and the rapid shift deflection can occur repeatedly, and more quickly, as additional frames are collected. Also, the ease of use for an operator is substantially improved with the de-coupling. In some examples, an operator can simply select the tilt angle, optionally optimizing the tilt angle over a range, e.g., at a single pixel. After optimization and other image quality characteristics are present (such as an absence of jitter), the operator can elect to proceed with a complete scan using the fast lateral scanning over the sample. In many examples, frame-based systems exhibit fewer artifacts given the rapid speed of scanning of a frame as compared to a completed frame in a pixel-based approach. Moreover, deleting and/or reacquiring additional frames to replace substandard frames can be more convenient given the increased speed of acquisition of frame-based approaches and multiple frames that are collected.

In some frame-based examples herein, a single beam deflector unit can be used to scan and tilt the beam, i.e., with coupled tilt and shift pivot points, so as to obtain frames such that each frame has a fixed (or only slowly varying tilt angle) throughout the frame. The single-scan unit examples may not operate as quickly or with reduced complexity, but they can be less expensive. Further, applying frame-based techniques using a single-scan unit in precession-type image collection can be less complex than the same collection using pixel-based approaches. This is because pivot point alignment requirements can be relaxed frame-based approaches. With a fixed tilt being applied, potential errors in shift can be more easily compensated based on the acquisition of the complete frame. For example, frames of a sequence can be compared, and cross-correlation or machine learning techniques can be used to detect image shifts or other image variations which can then be corrected. Post-process image processing 329 can include software routines configured to provide various image processing and/or image adjustments, including post-sample shift compensation, image construction using collected frames, feature detection, etc.

The tilt deflector parameters 326 can also include corrective de-tilt parameters for the beam deflector 318. The beam deflector 318 can provide de-tilting and stabilization of the diffraction pattern or image below the sample 306 due a tilt-induced image shift or diffraction shift. Notably, even with the de-coupling of tilt and shift preceding the sample 306, in many examples a single descan unit (or no scan unit) can be used after the sample 306 (because the tilt introduced does produce an image shift) without symmetrically requiring a second descan unit. In some examples, the post-process image processing 329 can be used to compensate for shifts between frames (e.g., associated with the change of tilt parameters between frames), including, in some examples, without use of a de-scan unit to de-tilt the collected image frames.

In some examples, the system 300 can include a drift compensator 330 that can be part of or coupled to the controller 324. During a tilt-based workflow in which images are acquired using a tilt, the beam 304 can become distorted, e.g., due to drift, and/or the sample position can drift during acquisition of the tilt matrix. Drift can occur due to environmental perturbations such as external vibrations, temperature changes, acoustic or pressure variations, as well as aberrations caused by system changes or nonlinearities. Frame-based approaches advantageously allow for the ability to compensate aberrations or drift effects during the frame acquisition process, dynamically or post-process. In some examples, the drift compensator 330 can be configured with feedback capability to dynamically make corrections during frame acquisition. In some instances, a drift can be detected by comparing identifiable features in a sequence of frames and a detected movement of the identified features can provide a basis for making corrections between frames. The drift compensator 330 can include or be embodied in computer readable instructions that can be used by the controller 324 or another processor-based computing system. The drift compensator 330 can include instructions to receive scan data, compare image data, and make adjustments to images or relationships between images. Many existing software modules can be leveraged to make comparisons and image corrections.

By way of example, because the beam is distorted due to optical aberration when tilted, a compensation to minimize these effects can be applied for each tilt. This can lead to higher lateral resolution, e.g., when adding up a precession run. In many examples, the beam tilt can cause a beam shift, such as where pivot point alignment is imperfect. These shifts can be compensated by cross correlation of the images with different tilt leading to higher lateral resolution of the result. In the diffraction plane a shift of the pattern can occur, e.g., when the descan unit is not perfectly aligned. By cross-correlation methods, or similar, these shifts can be compensated before adding the diffraction patterns for further analysis. This can increase the accuracy of the results e.g., in strain, orientation mapping, or center of mass analysis applications (e.g., field measurements, iDPC, ptychography, etc.). These compensations can be applied live during acquisition or in an offline process. By contrast, these effects cannot be compensated in pixel-based precession. This can lead to a blur in the scan plane (e.g., resulting in a loss of lateral resolution) or a blur in the diffraction plane leading to a loss of precision of the measurement. That is, pixel-based approaches generally produce only one blurred image and one (blurred) diffraction pattern per scanned pixel, so that these compensations cannot be executed.

Related compensation in pixel-based approaches also can be unavailable because when the beam is dynamically precessed, a single frame is acquired over a longer duration. A drift can occur that cannot be readily corrected without repeating acquisition of the entire pixel-based frame. Also, for aberrations, it is often too difficult or impossible to dynamically correct the aberrations in pixel-based approaches, even with a priori knowledge of the aberration through prediction, because the speed of the precession exceeds corrector capabilities. For example, modeling often provides predicted aberration amounts in response to applying varying amounts of tilt, and the expected aberrations can then be corrected with a lens, stigmator, or probe corrector. In some examples, the controller 324 can be configured with predicted aberration amounts and related commands for arrangement 312 and deflectors 314, 316 to adjust beam direction so that frames can be collected with reduced aberration. Aberration corrections can be made by leveraging the longer duration of a scanning an entire frame at the fixed tilt angle or the fewer fixed tilt angles that are applied to complete a workflow.

Some corrections can be applied in frame-based approaches by comparing features in acquired frames given the time provided to acquire a complete frame and given that the tilt angle and azimuth angle are maintained throughout the frame. Some corrections can be made based on model-based predictions of aberrations that can be stored in controller memory. This can allow for corrections of expected aberrations before a frame is collected at a selected tilt/azimuth angle. In contrast, with pixel-based approaches, the speed of precession of the beam at a pixel can be beyond the capability of a probe corrector to track, or related delays inserted into the process to match the corrector capability undesirably increase the length of an already lengthy workflow. In addition, pixel-based approaches build frame information pixel-by-pixel and so there is no complete frame information until the scanning process concludes. As such, it is not possible to apply corrections based upon, e.g., comparison of feature locations in a frame because there are not multiple frames to compare.

In some examples, frame-based tilt approaches can allow for adjustment of the number of azimuthal positions and tilt angles that are scanned. For example, whereas pixel-based approaches typically require the collection of hundreds of azimuthal positions at a pixel location, disclosed frame-based approaches can vary this number arbitrarily and can enjoy significant reductions in workflow durations by reducing the number of azimuthal positions, tilt angles, and therefore collected frames. For example, lower amounts can be sufficient to avoid channeling artifacts or to provide a composition analysis in the field or in the strain mapping. Moreover, the further reduction in workflow duration can lead to further improvements in drift reduction, as there is less time for drift to occur where fewer frames are collected or are collected more quickly.

With respect to channeling artifacts, when a crystal is in the zone axis the atoms are aligned in straight columns with respect to beam direction. When the electron beam is impinging upon the sample under such conditions, the electrons can channel through the material leading to an inhomogeneous distribution during their travel through the sample. As a result, columns with different atomic species see different amounts of electrons. Quantification in EDX/EELS assumes that the electrons travel homogeneously through the material so that the probability that an atom is excited is everywhere the same. When using precession by tilting the electron beam away from the zone axis, channeling can be minimized because the exact alignment of the beam with the atomic column is avoided. Multiple tilts can thereby simply average out this effect. Therefore, precession (e.g., rocking beam) acquisition in mapping can lead to more accurate compositional analysis. Also, precession has an advantage in COM analysis for E/B fields (that is, electric or magnetic fields) measurements because the change of the crystal orientation via precession is depending on the tilt angle of the beam while the COM change of the field is not altered. Therefore E/B fields can be measured more accurately in precession mapping in 4D STEM of crystalline materials than without.

### Example Frame and Matrix Formation and Additional Methods

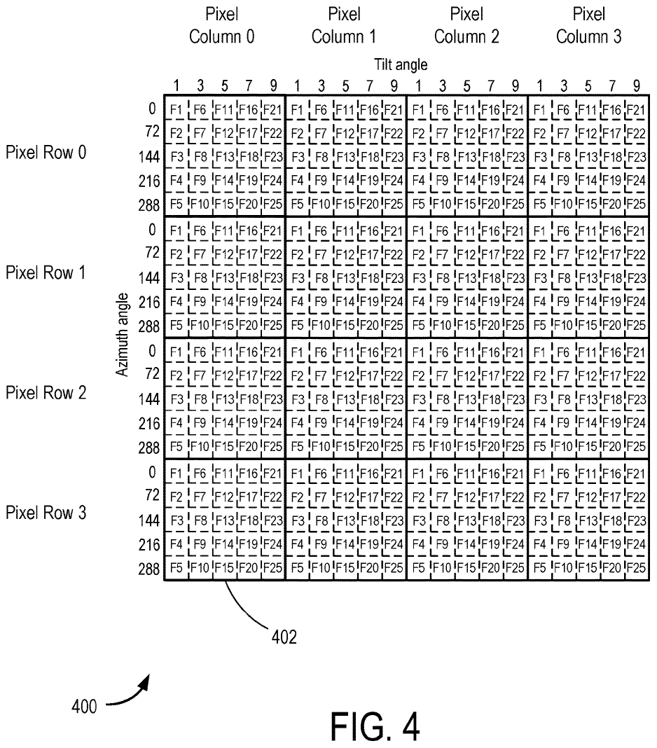

FIG. 4 is a representation of a 4×4 pixel array 400 showing sixteen tilt matrices 402 acquired in a frame-based precession workflow, each matrix 402 corresponding to one of the pixels of the array 400. Each tilt matrix 402 includes data for five tilt angles (1°, 3°, 5°, 7°, and 9°) at five azimuthal positions (0°, 72°, 144°, 216°, and 288°) acquired over the course of twenty-five frames. In the tilt matrices 402, the image data obtained for a particular tilt angle and azimuth angle frame is designated by the frame number from 1 to 25. In many examples, the array 400 is typically larger. The tilt matrices 402 can be configurable by the user or vary based on the application. For example, while a series of precessions at different tilt angles can be used as shown, a variety of other tilt patterns may be used depending on the application, including non-conical ones. By way of example, any of the beam tilt patterns described in U.S. application Ser. No. 17/683,076 “MEASUREMENT AND CORRECTION OF OPTICAL ABERRATIONS IN CHARGED PARTICLE BEAM MICROSCOPY,” incorporated herein by reference, may be used in frame-based tilt acquisitions, e.g., to correct aberrations in a TEM. In additional examples, rocking-beam type patterns may be used in frame-based tilt acquisitions. For example, azimuth angle changes can be limited to 0° and 180° as the beam varies tilt angle along an axis, similar to a movement of a pendulum.

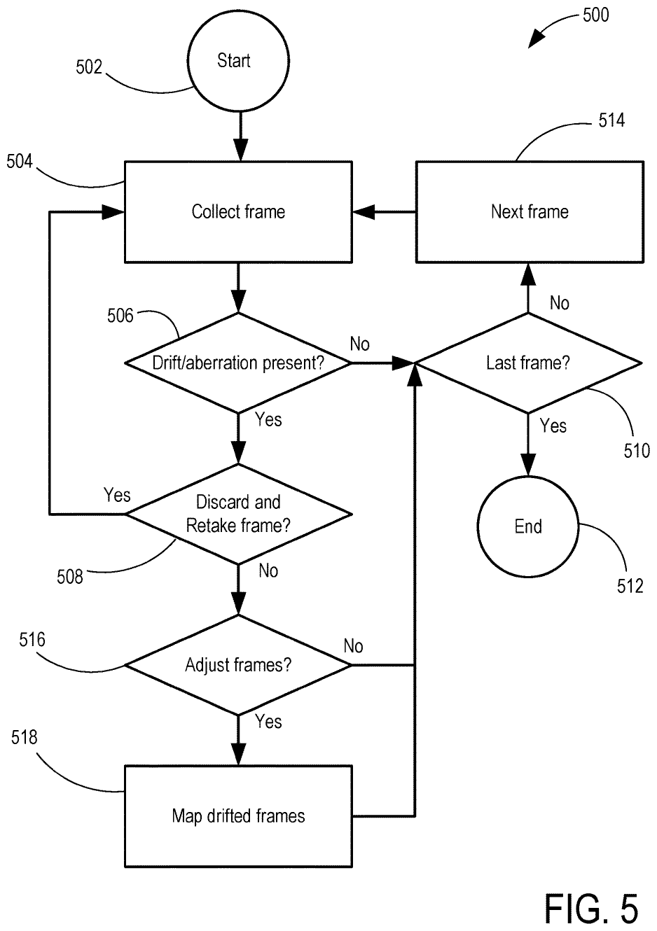

FIG. 5 is an example method 500 of frame collection with drift correction. At 502, the method 500 can start. At 504, a frame is collected for the series of frames. At 506, the collected frame can be examined to determine whether there is a drift or aberration present in the frame. In many examples, a comparison can be made with other collected frames, such as an immediately previous frame. If a drift is detected, then the process can proceed to check, at 508, against criteria to determine whether to discard and retake the frame. For example, a frame that includes artifacts or oddities that are inconsistent with other frames can be discarded and retaken at 504. In some examples, comparisons can be made later in the frame collection process or require additional time to process so that the determination is not available until later in the frame collection process.

Where a drift or aberration is not detected, at 510 it can be determined whether there are any more frames to collect, and if there are no frames to collect then the process can end at 512. If additional frames are to be collected, at 514, the next frame can be iterated, and the frame collection can continue back at 504. Where a frame is not to be discarded or retaken but a drift is detected, at 516, a determination as to whether to adjust frames can be made. For example, in some instances, a drift or aberration may be detected that is below a drift or aberration tolerance, in which case, the frames can be left unadjusted and the next frame can be iterated at 514. In some examples, at 518, frames can be adjusted through a mapping between frames. For example, where a drift is sufficient, frames can be compared to quantify the drift, e.g., in the form of a rotational and/translational movement in a sequence of frames. Other drift or aberration characteristics can be quantified, including image warping, distortion, stretching, or other aberrations. The mapping can be used so that a subsequent frame-based tilt matrix can be constructed with reduced effects from drift or other aberrations.

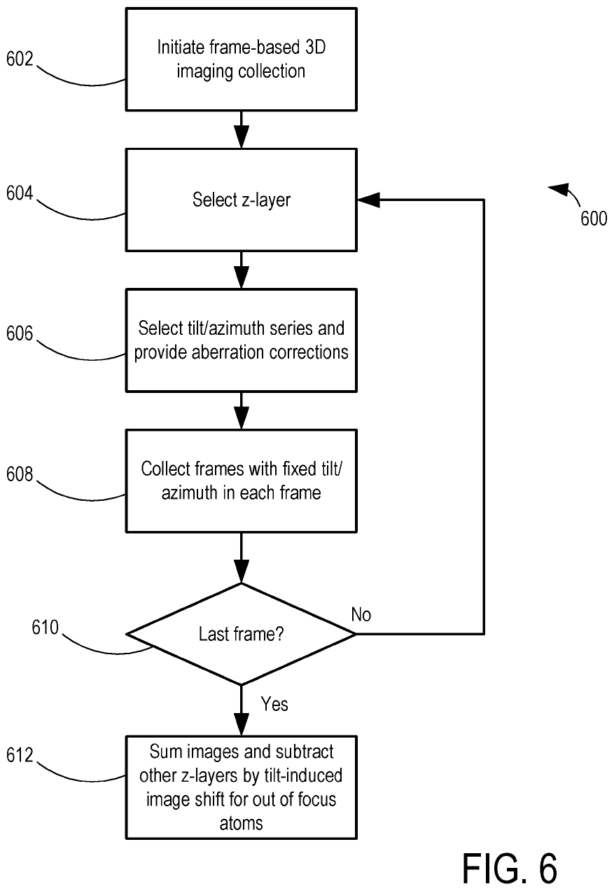

FIG. 6 is an example 3D imaging method 600 using frame-based collection techniques. At 602, the framed-based 3D imaging method can start. At 604, a z-layer of a sample is selected for targeting. A z-layer can correspond to a depth position of the sample along the general direction of the beam used for imaging. At 606, tilt and azimuth angles can be selected for probing the sample. Aberration correction can be provided based on the selected tilt and azimuth so that aberrations induced by the tilt of the beam have a reduced effect. For example, the probe spot at the selected z-layer can be elliptical due to the tilt angle and such ellipticity can be corrected with an aberration corrector or other lens element adjustments. At 608, frames can be collected using a fixed (or slowly varying) tilt and azimuth maintained throughout an individual frame. At 610, a determination can be made as to whether any additional frames are to be collected. For example, additional z-layers or tilt/azimuth angles may be imaged. If additional frames are to be imaged, then selection of a new z-layer and/or tilt/azimuth angle can occur at 604 and/or 606. If the last frame is imaged, then at 612, the collected tilt matrices can be filled with the collected data and images can be summed together. Due to the tilt angle, non-targeted z-layers can exhibit an image shift. Thus, by summing the image data at each pixel, other non-targeted z-layers can be subtracted from the image based on the tilt-induced image shift of the out-of-focus atoms of other layers. It will be appreciated that various frame sequences may be used in different examples. In some examples, a tilt/azimuth angle can be selected and frames for the selected tilt/azimuth angle being collected at various z-layer depths. In other examples, a frame sequence of different selected tilt/azimuth angles at a selected z-layer can be imaged and then repeated at different z-layers. In still further examples, frame sequences can include a combination of frame sequencing. Frame sequencing can be tailored based on various factors, such as acquisition speed, reduced aberrations or drift, preference, etc.

### General Considerations

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatus are referred to as “lowest”, “best”, “minimum,” or the like. It will be appreciated that such descriptions are intended to indicate that a selection among many used functional alternatives can be made, and such selections need not be better, smaller, or otherwise preferable to other selections.

The innovations can be described in the general context of computer-executable instructions, such as those included in program modules, being executed in a computing system on a target real or virtual processor. Generally, program modules or components include routines, programs, libraries, objects, classes, components, data structures, etc. that perform particular tasks or implement particular abstract data types. The functionality of the program modules may be combined or split between program modules as desired in various embodiments. Computer-executable instructions for program modules may be executed within a local or distributed computing system. In general, a computing system or computing device can be local or distributed, and can include any combination of special-purpose hardware and/or general-purpose hardware with software implementing the functionality described herein.

In various examples described herein, a module (e.g., component or engine) can be “coded” to perform certain operations or provide certain functionality, indicating that computer-executable instructions for the module can be executed to perform such operations, cause such operations to be performed, or to otherwise provide such functionality. Although functionality described with respect to a software component, module, or engine can be carried out as a discrete software unit (e.g., program, function, class method), it need not be implemented as a discrete unit. That is, the functionality can be incorporated into a larger or more general-purpose program, such as one or more lines of code in a larger or general-purpose program.

For the sake of presentation, the detailed description uses terms like “determine” and “use” to describe computer operations in a computing system. These terms are high-level abstractions for operations performed by a computer, and should not be confused with acts performed by a human being. The actual computer operations corresponding to these terms vary depending on implementation.

Described algorithms may be, for example, embodied as software or firmware instructions carried out by a digital computer or controller. For instance, any of the disclosed frame-based imaging techniques, drift compensations, shift compensations, aberration corrections, and/or automation techniques can be performed by one or more a computers or other computing hardware that is part of a microscopy tool. The computers can be computer systems comprising one or more processors (processing devices) and tangible, non-transitory computer-readable media (e.g., one or more optical media discs, volatile memory devices (such as DRAM or SRAM), or nonvolatile memory or storage devices (such as hard drives, NVRAM, and solid state drives (e.g., Flash drives)). The one or more processors can execute computer-executable instructions stored on one or more of the tangible, non-transitory computer-readable media, and thereby perform any of the disclosed techniques. For instance, software for performing any of the disclosed embodiments can be stored on the one or more volatile, non-transitory computer-readable media as computer-executable instructions, which when executed by the one or more processors, cause the one or more processors to perform any of the disclosed techniques or subsets of techniques. The results of the computations can be stored in the one or more tangible, non-transitory computer-readable storage media and/or can also be output to the user, for example, by displaying, on a display device, frame data, images (including combined images, diffraction patterns, etc.), tilt/azimuth parameters, tilt matrices, image drifts, and/or image drifts.

Having described and illustrated the principles of the disclosed technology with reference to the illustrated embodiments, it will be recognized that the illustrated embodiments can be modified in arrangement and detail without departing from such principles. For instance, elements of the illustrated embodiments shown in software may be implemented in hardware and vice-versa. Also, the technologies from any example can be combined with the technologies described in any one or more of the other examples. It will be appreciated that procedures and functions such as those described with reference to the illustrated examples can be implemented in a single hardware or software module, or separate modules can be provided. The particular arrangements above are provided for convenient illustration, and other arrangements can be used.

In view of the many possible embodiments to which the principles of the disclosed technology may be applied, it should be recognized that the illustrated embodiments are only representative examples and should not be taken as limiting the scope of the disclosure.

Alternatives specifically addressed in these sections are merely exemplary and do not constitute all possible alternatives to the embodiments described herein. For instance, various components of systems described herein may be combined in function and use.

The following paragraphs provide various examples of the embodiments disclosed herein.

Example 1 is a method, including directing a charged particle beam across an area of a target at a first angle having tilt and azimuth angle components, to collect a first image frame produced using the beam at the selected first angle, detecting the first image frame, directing the charged particle beam across the area of the target at a second angle having tilt and/or azimuth angle components different from the first angle tilt and azimuth angle components to collect a second image frame produced using the beam at the selected second angle, detecting the second image frame, and combining the first and second image frames to form an image.

Example 2 includes the subject matter of Example 1, and further specifies that the directing the beam across the area of the target comprises scanning the beam laterally with a lateral beam deflector, and wherein the directing the beam at the first and second angles comprises adjusting to the first and second angles with a tilt beam deflector.

Example 3 includes the subject matter of Example 2, and further specifies that the lateral beam deflector and tilt beam deflector are part of the same singular beam deflector unit.

Example 4 includes the subject matter of any of Examples 1-3, and further includes correcting for aberrations associated with directing the beam at the first angle and/or second angle before acquisition of the respective frame based on a prediction of the aberrations that would be induced at the first and/or second angle, wherein the correction comprises adjustment of one or more stigmators, deflectors, and/or lenses, upstream of the target.

Example 5 includes the subject matter of any of Examples 1-4, and further includes detecting a drift or aberration among collected frames and compensating for the drift or aberration.

Example 6 includes the subject matter of Example 5, and further specifies that the compensation is performed during the acquisition of the frames.

Example 7 includes the subject matter of any of Examples 1-6, and further specifies that the first and second angles comprise a set of tilt precession parameters.

Example 8 includes the subject matter of any of Examples 1-7, and further specifies that the first and second angles comprise a set of rocking-beam, random walk, harmonic, Lissajous, and/or periodic tilt parameters.

Example 9 includes the subject matter of any of Examples 1-8, and further includes collecting image frames at multiple layer depths of the target and summing images to produce a 3D image of the target based on the tilt-induced image shift for out-of-focus atoms at depths other than the target layer depth.

Example 10 includes the subject matter of any of Examples 2-9, and further includes de-tilting a detection beam emitted from the target with a separate beam deflector before the detecting the first image and/or second image frame.

Example 11 includes the subject matter of any of Examples 1-10, and further includes constructing a tilt matrix of collected data by associating data collected from different image frames to a common target location.

Example 12 includes the subject matter of any of Examples 1-11, and further specifies that the first and second image frames comprise image frames of diffraction patterns and and further includes: determining a shift in the first and/or second image frame associated with the respective first or second angle; and compensating for the shift in the combining the first and second image frames to form the image.

Example 13 includes the subject matter of Example 12, and further specifies that the diffraction patterns are part of a precession tilt series about a circle, wherein the detecting comprises detecting with a pixelated sensor, and wherein the combining comprises compiling the precession tilt series to form a full precession diffraction pattern of the circle.

Example 14 includes the subject matter of Example 13, and further specifies that the detecting the first image frame and/or second image frame comprises receiving a downstream beam with a detector without the beam being deflected by a downstream deflection unit.

Example 15 includes the subject matter of any of Examples 1-14, and further specifies that the first and second image frames comprise spectroscopy image frames, and wherein the detecting of the first and second image frames comprises detecting a HAADF signal having a shift associated with a difference between the first and second angles and compensating for the shift by cross correlating the image frames.

Example 16 includes the subject matter of Example 15, and further specifies that the spectroscopy image frames comprise EDX spectra of the same area of the target, and the first and second angles are configured to reduce spectroscopic channeling artifacts.

Example 17 includes the subject matter of any of Examples 12-16, and further specifies that the shift comprises shift artifacts in center-of-mass, ptychography, or spectroscopy mapping measurements.

Example 18 is an apparatus, including a microscope system configured to emit a charged particle beam and to direct the beam across an area of a target at a first angle having tilt and azimuth angle components, to collect a first image frame produced using the beam at the selected first angle, and to direct the beam across the area of the target at a second angle having tilt and/or azimuth angle components different from the first angle tilt and azimuth angle components, to collect a second image frame produced using the beam at the selected second angle, wherein the microscope system includes a detector configured to receive and detect the first and second image frames, wherein the microscope system includes a controller configured to combine the first and second image frames to form an image.

Example 19 includes the subject matter of Example 18, and further specifies that the microscope system comprises a lateral beam deflector configured to scan the beam laterally and a tilt beam deflector separate from the lateral beam deflector, wherein the tilt beam deflector is configured to direct the beam at the first angle and second angle.

Example 20 includes the subject matter of any of Examples 18-19, and further specifies that the controller is configured to correct for aberrations associated with directing the beam at the first angle and/or second angle by adjusting the beam directing before acquisition of the respective frame, based on a prediction of the aberrations that would be induced at the first and/or second angle.

Example 21 is a method, including directing a charged particle beam across an area of a target at a tilt angle and azimuth angle to collect an image frame produced using the beam at the selected tilt angle and azimuth angle, and detecting the collected image frame.

Example 22 includes the subject matter of Examples 21, and further includes repeating the directing and detecting one or more times using one or more different selected tilt angles and/or azimuth angles.

Example 23 includes the subject matter of any of Examples 21-22, and further specifies that the directing the beam across the area of the target comprises scanning the beam laterally with a lateral beam deflector configured to provide lateral scanning, and wherein the directing the beam at the tilt angle and azimuth angle comprises adjusting the tilt angle and azimuth angle of the beam with a tilt beam deflector separate from the lateral beam deflector.

Example 24 includes the subject matter of any of Examples 21-23, and further includes constructing a tilt matrix of collected data by associating data collected from different image frames to a common sample location.

Example 25 includes the subject matter of any of Examples 21-24, and further includes detecting a drift or aberration among collected frames and compensating for the drift or aberration.

Example 26 includes the subject matter of Example 25, and further specifies that the compensation is performed during the acquisition of the frames.

Example 27 includes the subject matter of any of Examples 22-26, and further specifies that the one or more different tilt angles and/or azimuth angles comprise a set of tilt precession parameters.

Example 28 includes the subject matter of any of Examples 22-27, and further specifies that the one or more different tilt angles and/or azimuth angles comprise a set of rocking-beam, random walk, harmonic, Lissajous, and/or periodic tilt parameters.

Example 29 includes the subject matter of any of Examples 22-28, and further includes collecting image frames at multiple layer depths of the sample and summing images to produce a 3D image of the sample based on the tilt-induced image shift for out-of-focus atoms at depths other than the target layer depth.

Example 30 includes the subject matter of any of Examples 23-29, and further includes de-tilting a detection beam emitted from the sample with a separate beam deflector before detection with the detector.

Example 31 is an apparatus, including a microscope system configured to emit a beam and to direct the beam across an area of a target at a tilt angle and azimuth angle to collect an image frame produced using the beam at the selected tilt angle and azimuth angle, wherein the microscope system includes a detector configured to receive and detect the collected image frame.

Example 32 includes the subject matter of Example 31, and further specifies that the microscope system is configured to repeat the directing and detecting one or more times using one or more different selected tilt angles and/or azimuth angles.

Example 33 includes the subject matter of any of Examples 31-32, and further specifies that the microscope system comprises a lateral beam deflector configured to scan the beam laterally and a tilt beam deflector separate from the lateral beam deflector, wherein the tilt beam deflector is configured to direct the beam at the tilt angle and azimuth angle.

Example 34 includes the subject matter of any of Examples 31-33, and further specifies that the microscope system includes a frame-based imaging controller configured to construct a tilt matrix of collected data by associating data collected from different image frames to a common sample location.

Example 35 includes the subject matter of any of Examples 31-34, and further specifies that the microscope system includes a frame-based imaging controller configured to detect a drift or aberration among collected frames and to compensate for the drift or aberration.

Example 36 includes the subject matter of Example 35, and further specifies that the frame-based imaging controller is configured to provide the compensation during the acquisition of the frames.

Example 37 includes the subject matter of any of Examples 32-36, and further specifies that the one or more different tilt angles and/or azimuth angles comprise a set of tilt precession parameters.

Example 38 includes the subject matter of any of Examples 32-37, and further specifies that the one or more different tilt angles and/or azimuth angles comprise a set of rocking-beam, random walk, harmonic, Lissajous, and/or periodic tilt parameters.

Example 39 includes the subject matter of any of Examples 32-38, and further specifies that the microscope system is configured to collect image frames at multiple layer depths of the sample and to sum images to produce a 3D image of the sample based on the tilt-induced image shift for out-of-focus atoms at depths other than the target layer depth.

Example 40 includes the subject matter of any of Examples 33-39, and further includes a separate beam deflector configured to de-tilt a detection beam emitted from the sample before detection with the detector.

Example 41 includes one or more non-transitory computer-readable media having instructions thereon that, when executed by one or more processing devices of a charged particle microscope apparatus or supporting apparatus, cause the apparatus to perform any of the operations of any of Examples 1-40.

1. A method, comprising:
directing a charged particle beam across an area of a target at a first angle having tilt and azimuth angle components, to collect a first image frame produced using the beam at the selected first angle;
detecting the first image frame;
directing the charged particle beam across the area of the target at a second angle having tilt and/or azimuth angle components different from the first angle tilt and azimuth angle components to collect a second image frame produced using the beam at the selected second angle;
detecting the second image frame; and
combining the first and second image frames to form an image.

2. The method of claim 1, wherein the directing the beam across the area of the target comprises scanning the beam laterally with a lateral beam deflector, and wherein the directing the beam at the first and second angles comprises adjusting to the first and second angles with a tilt beam deflector.

3. The method of claim 2, wherein the lateral beam deflector and tilt beam deflector are part of the same singular beam deflector unit.

4. The method of claim 1, further comprising correcting for aberrations associated with directing the beam at the first angle and/or second angle before acquisition of the respective frame based on a prediction of the aberrations that would be induced at the first and/or second angle, wherein the correction comprises adjustment of one or more stigmators, deflectors, and/or lenses, upstream of the target.

5. The method of claim 1, further comprising detecting a drift or aberration among collected frames and compensating for the drift or aberration.

6. The method of claim 5, wherein the compensation is performed during the acquisition of the frames.

7. The method of claim 1, wherein the first and second angles comprise a set of tilt precession parameters.

8. The method of claim 1, wherein the first and second angles comprise a set of rocking-beam, random walk, harmonic, Lissajous, and/or periodic tilt parameters.

9. The method of claim 1, further comprising collecting image frames at multiple layer depths of the target and summing images to produce a 3D image of the target based on the tilt-induced image shift for out-of-focus atoms at depths other than the target layer depth.

10. The method of claim 2, further comprising de-tilting a detection beam emitted from the target with a separate beam deflector before the detecting the first image and/or second image frame.

11. The method of claim 1, further comprising constructing a tilt matrix of collected data by associating data collected from different image frames to a common target location.

12. The method of claim 1, wherein the first and second image frames comprise image frames of diffraction patterns and further comprising:
determining a shift in the first and/or second image frame associated with the respective first or second angle; and
compensating for the shift in the combining the first and second image frames to form the image.

13. The method of claim 12, wherein the diffraction patterns are part of a precession tilt series about a circle, wherein the detecting comprises detecting with a pixelated sensor, and wherein the combining comprises compiling the precession tilt series to form a full precession diffraction pattern of the circle.

14. The method of claim 13, wherein the detecting the first image frame and/or second image frame comprises receiving a downstream beam with a detector without the beam being deflected by a downstream deflection unit.

15. The method of claim 1, wherein the first and second image frames comprise spectroscopy image frames, and wherein the detecting of the first and second image frames comprises detecting a HAADF signal having a shift associated with a difference between the first and second angles and compensating for the shift by cross correlating the image frames.

16. The method of claim 15, wherein the spectroscopy image frames comprise EDX or EELS spectra of the same area of the target, and the first and second angles are configured to reduce spectroscopic channeling artifacts.

17. The method of claim 12, wherein the shift comprises shift artifacts in center-of-mass, ptychography, or spectroscopy mapping measurements.

18. An apparatus, comprising:
a microscope system configured to emit a charged particle beam and to direct the beam across an area of a target at a first angle having tilt and azimuth angle components, to collect a first image frame produced using the beam at the selected first angle, and to direct the beam across the area of the target at a second angle having tilt and/or azimuth angle components different from the first angle tilt and azimuth angle components, to collect a second image frame produced using the beam at the selected second angle;
wherein the microscope system includes a detector configured to receive and detect the first and second image frames;
wherein the microscope system includes a controller configured to combine the first and second image frames to form an image.

19. The apparatus of claim 18, wherein the microscope system comprises a lateral beam deflector configured to scan the beam laterally and a tilt beam deflector separate from the lateral beam deflector, wherein the tilt beam deflector is configured to direct the beam at the first angle and second angle.

20. The apparatus of claim 18, wherein the controller is configured to correct for aberrations associated with directing the beam at the first angle and/or second angle by adjusting the beam directing before acquisition of the respective frame, based on a prediction of the aberrations that would be induced at the first and/or second angle.
